(19) United States
(12) Patent Application Publication
(10) Pub. No.: US 2009/0147464 A1
(43) Pub. Date: Jun. 11, 2009

(54) Ventilation Assembly for Computer Hardware Systems

(76) Inventors: William James Anderl, Rochester, MN (US); Terry Fredrick Banitt, Altura, MN (US); Eric Alan Eckberg, Rochester, MN (US); Don Alan Gilliland, Rochester, MN (US); Michael Scott Good, Fountain, MN (US); Mark David Pfeifer, Owatonna, MN (US); Daniel A. Wright, Rochester, MN (US)

Correspondence Address: IBM-Rochester c/o Toler Law Group, 8500 Bluffstone Cove, Suite A201, Austin, TX, 78759, US

(21) Appl. No.: 11/953,433

(22) Filed: Dec. 10, 2007

(51) Int. Cl. H05K 7/20; H05K 5/00

(52) U.S. Cl. 361/679.46

(57) ABSTRACT

An assembly for dissipating heat generated by electronic components which include a ventilating panel having a plurality of vent holes arranged thereon. More specifically, the perforation pattern of vent holes is staggered to provide adjacent larger and smaller vent holes in at least two rows of vent holes. A second row of vent holes is staggered with respect to the first row of vent holes such that the larger vent holes are aligned with smaller vent holes, preferably in a ratio of two smaller vent holes per one larger vent hole. Such a perforation arrangement of vent holes may be provided on a blindswap cassette for securing and aligning computer cards for mounting in a housing, such as a sled for use in computer systems.

### FIELD OF THE INVENTION

This invention relates generally to a ventilation assembly for computer systems providing improved thermal and EMI shielding performance, and more particularly, to blindswap cassettes having such ventilation assemblies for computer cards arranged in computer card sleds.

### BACKGROUND OF THE INVENTION

Market demands for processing intensive applications have resulted in an ever increasing demand for computing systems that operate at higher speeds. In addition, market preferences generally dictate that smaller system packages are preferred to larger system packages. Typically, computer systems are cooled by one or more fans mounted to the interior of a chassis that blow air across the applicable electronic components and transfer heat through convection.

The trend towards smaller packages, while at the same time increasing the available computing power of the systems, has increased the amount of heat generated within the systems. Thus, effective and reliable cooling has become more important while maintaining adequate EMI shielding.

In addition to such computing systems, subassemblies, such as sleds for an array of PCI or PCIE cards, also generate significant amounts of heat and require effective cooling. Cooling assemblies for such devices also require that EMI be minimized.

Failing to provide adequate cooling can result in the loss of valuable computing resources, as well as the expenditure of increased resources to recover lost data. Thus, achieving market place success dictates that manufacturers design increasingly efficient mechanisms and systems for dissipating heat within a computer system without significantly increasing costs, complexity, or package size.

### SUMMARY OF THE INVENTION

In accordance with one aspect of the invention, there is provided an assembly for dissipating heat generated by electronic components housed, for example, within a computer chassis. A computer chassis may be dimensioned to substantially enclose electronic components. The computer chassis may include at least one ventilating panel. The ventilating panel may include a plurality of vent holes from perforations typically arranged thereon. The vent holes are typically arranged in at least two rows, wherein the vent holes are sized such that a first plurality of the vent holes are larger than a second plurality. Preferably, larger vent holes are arranged adjacent smaller vent holes on the sides thereof. In a more specific aspect, the arrangement of rows in any row is such that a pair of smaller vent holes is followed in sequence by a larger vent hole, and then by a smaller pair of vent holes, and so on. An adjacent row is staggered in the same manner, but in reverse order such that pairs of smaller vent holes in the adjacent row are arranged in such a manner as to be aligned with the larger vent holes of the first row. In this manner, adequate air circulation is maintained while EMI is minimized as compared to a prior art arrangement having only larger vent holes.

Another aspect the invention relates to a computer chassis panel that includes an arrangement of vent holes substantially as described with respect to the aforementioned assembly embodiment.

Further alternative embodiments of the invention relate to a blindswap cassette. The cassette is typically of the type used for assembling computer cards in an aligned manner within a cassette sled. Such cassette sleds are typically used for holding computer cards such as PCI and PCIE cards therein as part of an overall computer assembly. The blindswap cassette may include an engagement member for having a computer card held thereon, such as a slot, so that the computer card can be guided and secured within a sled. A securing clip may be provided for releasably securing the blindswap cassette within the sled. The engagement member may include a plurality of vent holes arranged so at least along one side thereof there are at least two rows of vent holes resulting from perforations in the engagement member. The vent holes may be arranged in a manner substantially as previously described. Preferably, the arrangement of vent holes is provided on both sides of the cassette, and specifically, the engagement members. In a more preferred aspect, each row is arranged such that two smaller vent holes are on either side of a respective larger vent hole. A second row may be adjacent to the first row and has a similar vent hole arrangement, but may be staggered relative to the first hole such that pairs of smaller vent holes of the second row are arranged adjacent to a larger vent hole of the first row.

These and other advantages and features that characterize the invention are set forth in the claims annexed hereto and forming a further part hereof. However, for a better understanding of the invention, and of the advantages and objectives obtained through its use, reference should be made to the Drawings, and to the accompanying descriptive matter, in which there are described exemplary embodiments of the invention.

### BRIEF DESCRIPTION OF THE DRAWINGS

FIG. 1 is a perspective view of a sled for a computer assembly containing a plurality of blindswap cassettes implementing a ventilating vent hole arrangement;

FIG. 2 is a side view of a blindswap cassette having a PCI card mounted thereon, and showing in part a vent hole arrangement in accordance with aspects of the invention;

FIG. 3 is a perspective end view of a blindswap cassette showing a ventilating arrangement as implemented on blindswap cassette mounted within computer assemblies;

FIG. 4 is an enlarged partial view of a section of a blindswap cartridge implementing a ventilating arrangement in accordance with the invention, and which can also be implemented on a multitude of other computer assemblies;

FIG. 5 is a table illustrating improved EMC performance resulting from a ventilating arrangement implemented on blindswap cassettes, as compared to prior art blindswap cassettes having all large ventilating holes; and

FIG. 6 is a perspective view of a chassis containing electronic components showing a ventilating arrangement according to the invention as implemented on a panel thereof.

### DETAILED DESCRIPTION OF THE PREFERRED EMBODIMENTS

Embodiments consistent with the principles of the present invention provide, among other features, a ventilating arrangement for computer assemblies. Such a ventilating arrangement provides adequate ventilation while improving EMC. The computer assemblies may include a chassis containing electronic components therein. The ventilating arrangement may be provided on one or more panels thereof. In a more specific aspect, the ventilating arrangement may be provided on blindswap cassettes for computer cards, such as PCI and PCIE cards. Such cards are typically mounted in card sleds and are part of larger and more complex computer assemblies. Such blindswap cassettes are typically used to secure a card thereon and to guide them into corresponding slots, for example, in a cassette sled. There is typically a plurality of blindswap cassettes and cards mounted within a single sled for connection to the remaining electronic components.

The ventilating arrangement includes at least two rows of vent holes. Some of the vent holes may be smaller in size than other vent holes and may be arranged in a specific configuration to enhance ventilation. This enhancement may improve thermal performance while minimizing EMI. In accordance with aspects of the invention the aperture size of the vent holes made by perforations are minimized as compared to the prior art without impacting air flow pressure impedance. By replacing a selected number of large aperture vent holes with smaller ones, air flow is maintained as a result of using smaller holes, albeit in a larger number. More specifically, in accordance with aspects of the invention, a perforation pattern of one larger and two smaller apertures, or vent holes, is provided in a first row. A second row of vent holes resulting from such perforations may be staggered such that the larger vent holes are aligned with two smaller vent holes of the first row. By staggering the small and large vent holes, the effective vent hole size is close to that of the smaller aperture.

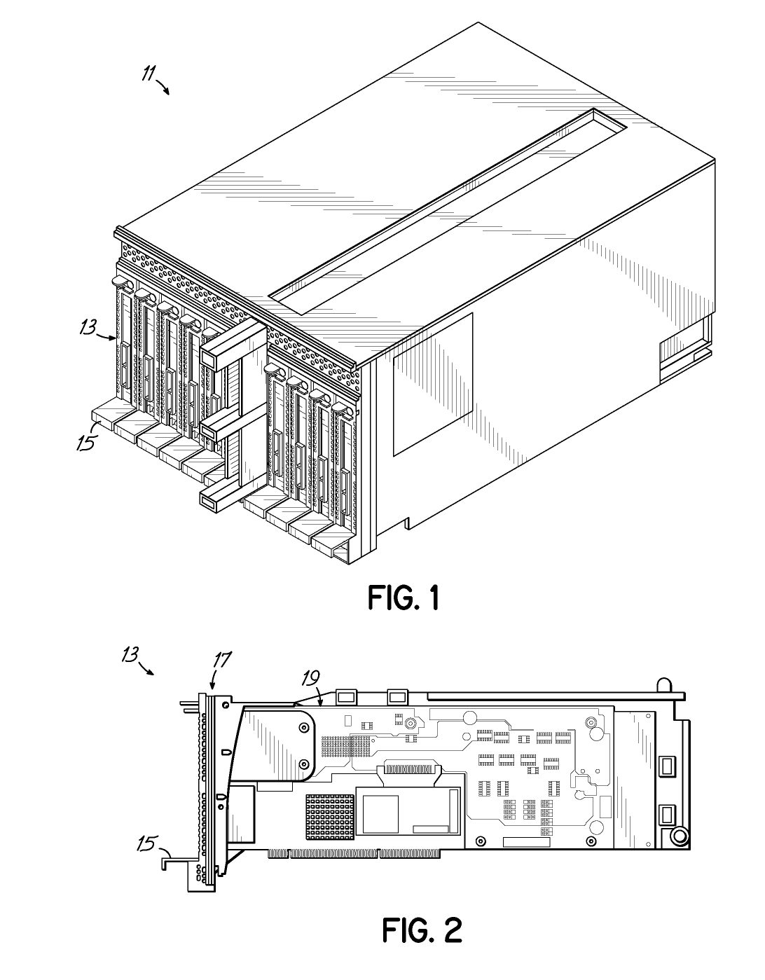

FIG. 1 is a perspective view of a computer card sled 11 having a plurality of blindswap cassettes 13 mounted therein. The cassettes 13 are of the type on which embodiments of the invention may be implemented, and include insertion handles 15 on each, which are modified to implement additional features of the ventilating arrangement of the invention.

FIG. 2 is a side view of a blindswap cassette 13 that includes a modified insertion handle 15, and an engagement member 17 that includes a slot for receiving a computer card 19, such as a PCI or PCIE card for insertion and alignment within the computer card sled.

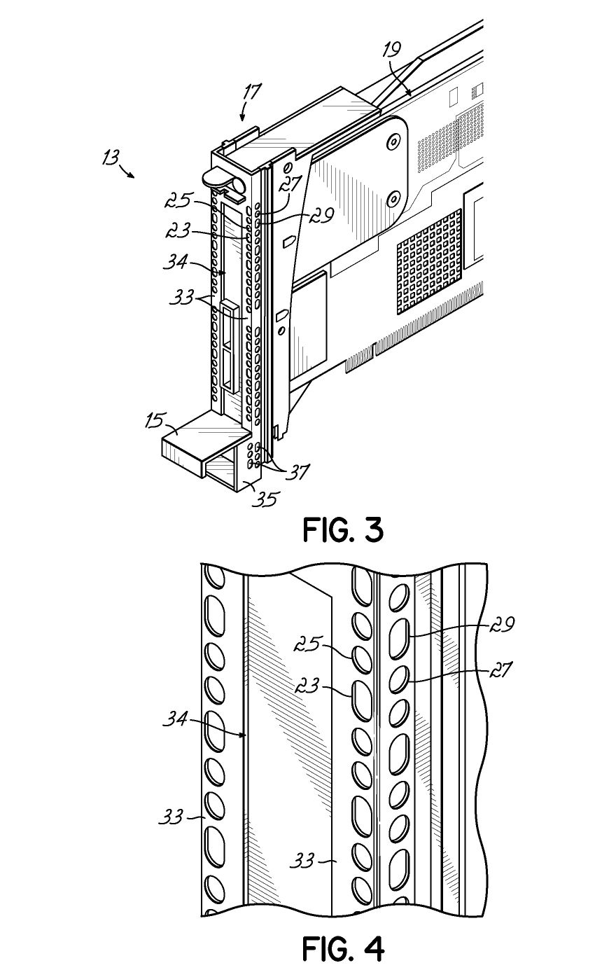

FIG. 3 illustrates in partial perspective view the blindswap cassette 13 with a handle 15 mounted on a lower mounting assembly 35. A computer card 19 such as a PCI or PCIE card is mounted within a slot 34 of the engagement member 17. The engagement member 17 is sized to receive a computer card 19 therein. Side edges 33 make up part of the engagement member 17 and include respectively, two rows of vent holes from perforations of different sizes. A first row includes an alternating arrangement of larger vent holes 23 having adjacent on either side thereof a pair of smaller vent holes 25. The second row is a similar arrangement to that of the first row but staggered in relation thereto, such that smaller vent holes 27 of the second row are arranged adjacent larger vent holes 23 of the first row, and larger vent holes 29 of the second row are arranged adjacent to smaller vent holes 25 of the first row.

FIG. 4 illustrates in a partial enlarged view a section of the engagement member 17 (FIG. 3) showing the staggered arrangement of smaller vent holes 25 and larger vent holes 23 in the first row arranged in relationship to the smaller vent holes 27 and larger vent holes 29 of the second row. While in a preferred aspect, the invention is implemented on such blindswap cassettes 13 (FIG. 3) as alternating pairs of smaller vent holes and straddling larger vent holes, it will be appreciated that alternative arrangements may be contemplated. For example, it may be possible that instead of having pairs of smaller vent holes, a single smaller vent hole may be made slightly larger and placed adjacent a larger vent hole, while still providing adequate EMC performance. Similarly, it may be possible to have four smaller vent holes adjacent each side of a larger vent hole, etc.

Referring again to FIG. 3, there is also illustrated a lower support member 35 that supports insertion handle 15. The lower support member 35 may be further modified to provide additional ventilation by having an arrangement of vent holes or perforations 37 arranged thereon substantially as previously described with respect to the engagement member 17.

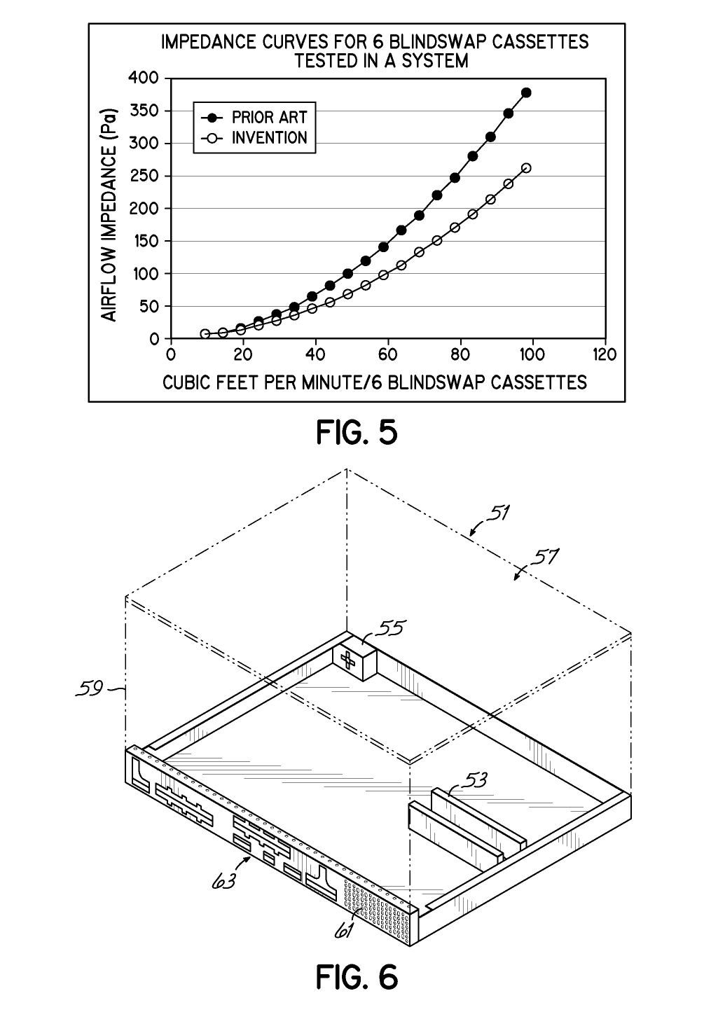

FIG. 5 is a table illustrating improvement in EMC performance in blindswap cassettes in accordance with aspects of the invention for an arrangement of six blindswap cassettes mounted in a manner to measure performance. As compared to the prior art, the performance improvement is noticeable. In a more specific aspect, the prior art cassettes included apertures, or vent holes, which were typically 6 mm. Based on common frequencies in computer systems, the recommended aperture is about 3 mm maximum for proper EMI shielding. By placing larger apertures, e.g. greater than 3 mm, next to smaller apertures, e.g., smaller than 3 mm, the effective result of EMI shielding is close to that of the smaller aperture. In terms of the hole shapes, they can be circular, rectangular, hexagonal, or array other configuration ensuring adequate air flow. In the preferred embodiment optimum air flow and shielding is achieved with rectangular holes with rounded corners.

More specifically, as a result of the arrangement of the invention, resistance to airflow is decreased as shown in the table. This test was done with all electronic components turned off as the test was concerned only with airflow testing. When the system was turned on significant improvement in EMI shielding was observed in the 2.5-5 GHz range.

FIG. 6 illustrates an alternative implementation of the invention on a chassis 51 having panels 57 that include a back panel 59 thereof for housing electronic components 53. The chassis 51 might house a computer assembly that includes multiple electronic components 53 and a fan 55 to provide ventilation. In accordance with an alternative aspect of the invention, a ventilating panel 61 includes an arrangement of vent holes arranged in at least two rows, and preferably a plurality of rows in a staggered arrangement as described previously. In one aspect, the ventilation panel 61 may be mounted on a rear panel 59 of the chassis 51, although similar ventilating panels may be provided on other panels 57 of the chassis 51. When implemented in a back panel 59 of a chassis 51 housing electronic components making up a computer assembly, the rear panel 59 may also include a set of slots 63 suitable for providing external access to adapter cards within the computer chassis assembly 51.

While the present invention has been illustrated by a description of various embodiments and while these embodiments have been described in considerable detail, it is not the intention of the Applicants to restrict, or any way limit, the scope of the appended claims to such detail. The invention in its broader aspects is therefore not limited to the specific details, representative apparatus, and illustrative examples as shown and described. Accordingly, departures may be made from such details without departing from the spirit or scope of Applicants' general inventive concept. Having thus described the invention, the same will become better understood from the appended claims in which it is set forth in a nonlimiting manner.

1. An assembly for dissipating heat generated by electronic components, comprising:
a computer chassis dimensioned to substantially enclose the electronic components; and
at least one substantially planar ventilating panel on said computer chassis, said ventilating panel having a plurality of vent holes arranged thereon and configured to minimize electromagnetic interference while facilitating airflow, said plurality of vent holes arranged in at least two rows with a first row having vent holes arranged in a pattern of larger holes with adjacent smaller holes, and a second row with vent holes arranged in the same pattern of the first row, said second row of vent holes arranged staggered relative to the first row for having a larger hole thereof adjacent smaller holes of the first row.

2. The assembly of claim 1, wherein said panel extends along exterior to the computer chassis along a back wall thereof

3. The assembly of claim 1, wherein the holes are shaped as rectangles having rounded corners.

4. The assembly of claim 1, wherein said at least a first row of smaller vent holes and said at least a second row of larger vent holes comprises more than two rows of alternating hole sizes.

5. The assembly of claim 2, wherein the back wall of the computer chassis further comprises a set of slots suitable for providing external access to adapter cards, within the chassis.

6. The assembly of claim 1, wherein said arrangement of vent holes comprises pairs of smaller vent holes arranged adjacent larger vent holes in the row.

7. A substantially planar computer chassis panel, comprising:
at least a first row of holes on said panel that are arranged in a pattern of a larger hole with adjacent smaller holes on each side;
at least a second row of holes on said panel that are arranged in a pattern of a larger hole with adjacent smaller holes on each side; and
the smaller vent holes of one of the two rows being aligned adjacent to a larger hole of the other row, wherein the first and second rows are configured to minimize electromagnetic interference while facilitating airflow.

8. The computer chassis panel of claim 7, wherein the holes are shaped as rectangles having rounded corners.

9. The computer chassis panel of claim 7, wherein said at least a first row of holes on said panel is arranged in a pattern of a larger hole with adjacent smaller holes on each side.

10. The computer chassis panel of claim 1, wherein said arrangement of vent holes comprises pairs of smaller vent holes arranged adjacent larger vent holes in the row.

11. A blindswap cassette, comprising:
an engagement member for having a computer card held thereon for guiding and securing said computer card in a computer card sled;
a securing clip for releasably securing said blindswap cassette within a computer card sled; and
said engagement member having a plurality of vent holes arranged along the length of at least one substantially planar side edge thereof, a first row having larger vent holes arranged with smaller vent holes on either side, and a second row that extends along said length of said engagement member, with vent holes arranged like those of the first row, and the smaller vent holes of one of the rows being aligned adjacent to the larger holes of the other row and configured to minimize electromagnetic interference while facilitating airflow.

12. The blindswap cassette of claim 11, wherein said engagement member has two side edges along the length thereof configured for engaging a computer card, said side edges each having at least two rows of said vent holes with one row adjacent to the other.

13. The blindswap cassette of claim 12, further comprising a computer card sled; and
a plurality of said blindswap cassettes engaged within corresponding engagement slots of said computer card sled.

14. The blindswap cassette of claim 13, wherein each blindswap cassette has a computer card mounted thereon.

15. The blindswap cassette of claim 13, wherein said computer card sled is a PCI card sled.

16. The blindswap cassette of claim 13, wherein said computer card sled is a PCIE card sled.

17. The blindswap cassette of claim 16, further comprising vent holes arranged at both sides of the engagement member.

18. The blindswap cassette of claim 11, wherein the holes are shaped as rectangles having rounded corners.

19. The blindswap cassette of claim 11, wherein said smaller vent holes and larger vent holes are sized to provide EMI shielding performance that achieves the effective size close to the smaller vent holes.

20. The blindswap cassette of claim 11, wherein said arrangement of vent holes comprises pairs of smaller vent holes arranged adjacent larger vent holes in the row.
